(19) United States
(12) Patent Application Publication
(10) Pub. No.: US 2025/0200364 A1
(43) Pub. Date: Jun. 19, 2025

(54) CLASSIFICATION ENGINE TRAINING METHOD FOR SEMICONDUCTOR INTEGRATED CIRCUIT, CLASSIFICATION METHOD FOR SEMICONDUCTOR INTEGRATED CIRCUIT, AND DESIGN METHOD FOR SEMICONDUCTOR INTEGRATED CIRCUIT

(71) Applicant: Socionext Inc., Kanagawa (JP)

(72) Inventor: Yukihiro SASAGAWA, Yokohama (JP)

(21) Appl. No.: 18/977,108

(22) Filed: Dec. 11, 2024

(30) Foreign Application Priority Data
Dec. 19, 2023 (JP) 2023-214278
Nov. 14, 2024 (JP) 2024-199158

(51) Int. Cl. G06N 3/08; G06F 30/323

(52) U.S. Cl. CPC G06N 3/08; G06F 30/323

(57) ABSTRACT

A classification engine training method for a semiconductor integrated circuit includes: obtaining a base design data item corresponding to each of one or more hardware structure information items; generating a plurality of additional design data items; and training a neural network using each of the plurality of additional design data items as an input. The plurality of additional design data items each include a partial base design data item that is a portion of the base design data item. One major ID value is assigned to each of the one or more hardware structure information items. In the training, the neural network is trained using each of the plurality of additional design data items as the input, to infer one major ID value corresponding to the additional design data item to be used as the input.

### CROSS REFERENCE TO RELATED APPLICATIONS

The present application is based on and claims priority of Japanese Patent Application No. 2023-214278 filed on Dec. 19, 2023 and Japanese Patent Application No. 2024-199158 filed on Nov. 14, 2024. The entire disclosure of the above-identified applications, including the specifications, drawings and claims are incorporated herein by reference in their entirety.

### FIELD

The present disclosure relates to a classification engine training method for a semiconductor integrated circuit, a classification method for a semiconductor integrated circuit, and a design method for a semiconductor integrated circuit.

### BACKGROUND

Conventionally, design methods for a semiconductor integrated circuit have been considered. A step of generating information necessary for designing and manufacturing a semiconductor integrated circuit includes many stages from an initial stage such as determining operating specifications expressed by hardware structure information described in a hardware description language to a final stage such as a layout of each constituent element and wiring of the semiconductor integrated circuit.

An electronic design automation (EDA) tool for automating a layout stage among those stages is available. It is possible to automate the layout stage by using such a tool.

### CITATION LIST

### Patent Literature

PTL 1: Japanese Unexamined Patent Application Publication (Translation of PCT Application) No. 2022-533704

### Non Patent Literature

NPL 1: Jure Leskovec and Christos Faloutsos, “Sampling from Large Graphs”, KDD'06, Aug. 20-23, 2006, Philadelphia, Pennsylvania, USA

### SUMMARY

### Technical Problem

Designing a layout using such a tool usually requires a lot of computational resources and a lot of time.

There is a technique called a warm start in which, when a layout is designed using the EDA tool, layout data serving as a base is used as an initial value to reduce computational resources and time. However, although it is possible to use designed layout data as an initial value when hardware structure information is, for example, hardware structure information derived from hardware structure information in which a layout is already designed, it is generally difficult to select layout data as an initial value when hardware structure information is not such hardware structure information. Moreover, when layout data used as an initial value is inappropriate, design quality may deteriorate. In such a technical field, for example, Patent Literature (PTL) 1 discloses a classification method for a layout but fails to disclose a method for selecting layout data suitable for an initial value in the warm start.

In view of the above, the present disclosure has an object to make it easy to select a layout data item appropriate as an initial value used in the warm start, in automating layout design for a semiconductor integrated circuit.

### Solution to Problem

In order to achieve the above object, a classification engine training method for a semiconductor integrated circuit according to one aspect of the present disclosure, the classification engine training method comprising: obtaining a base design data item corresponding to each of one or more hardware structure information items that describe the semiconductor integrated circuit and are different from each other; generating a training design data set including a plurality of additional design data items, based on the base design data item; and training a neural network using each of the plurality of additional design data items as an input, wherein the plurality of additional design data items are different from each other, and each includes a partial base design data item that is a portion of the base design data item and different from the base design data item, one major ID value is assigned to each of the one or more hardware structure information items, the one major ID value being included in one or more major ID values different from each other, and in the training, the neural network is trained using each of the plurality of additional design data items as the input, to infer one major ID value corresponding to the additional design data item to be used as the input, the one major ID value corresponding to the additional design data item being included in the one or more major ID values.

In order to achieve the above object, a classification method for a semiconductor integrated circuit according to one aspect of the present disclosure, the classification method comprising: assigning one major ID value to each of a plurality of hardware structure information items, based on the plurality of hardware structure information items and a layout data item about a semiconductor integrated circuit, the one major ID value being included in a plurality of major ID values different from each other, the plurality of hardware structure information items describing the semiconductor integrated circuit and being different from each other, the layout data item being generated based on each of the plurality of hardware structure information items; obtaining an unclassified base design data item corresponding to an unclassified hardware structure information item different from the plurality of hardware structure information items; and inferring one major ID value corresponding to the unclassified base design data item, by inputting the unclassified base design data item to a neural network trained, the one major ID value corresponding to the unclassified base design data item being included in the plurality of major ID values.

In order to achieve the above object, a design method for a semiconductor integrated circuit according to one aspect of the present disclosure, the design method comprising: classifying the unclassified hardware structure information item by inferring the one major ID value by the classification method for the semiconductor integrated circuit; and generating a layout data item which is based on the unclassified hardware structure information item, based on one hardware structure information item to which the one major ID value is assigned, and a design data item relating to a layout data item generated based on the one hardware structure information item, the one hardware structure information item being included in the plurality of hardware structure information items.

### Advantageous Effects

The present disclosure makes it easy to select a layout data item appropriate as an initial value used in the warm start, in automating layout design for a semiconductor integrated circuit.

### BRIEF DESCRIPTION OF DRAWINGS

These and other advantages and features will become apparent from the following description thereof taken in conjunction with the accompanying Drawings, by way of non-limiting examples of embodiments disclosed herein.

FIG. 1 is a block diagram illustrating the entire configuration of a design system for a semiconductor integrated circuit according to Embodiment 1.

FIG. 2 is a block diagram illustrating the functional configuration of a classification engine training device according to Embodiment 1.

FIG. 3 is a diagram illustrating an example of a base graph object according to Embodiment 1.

FIG. 4 is a block diagram illustrating the functional configuration of a classification engine according to Embodiment 1.

FIG. 5 is a diagram illustrating an example of the hardware configuration of a computer that implements the functions of the design system for the semiconductor integrated circuit according to Embodiment 1, using software.

FIG. 6 is a flow chart illustrating steps in a classification engine training method for a semiconductor integrated circuit according to Embodiment 1.

FIG. 7 is a flow chart illustrating steps in a classification method for a semiconductor integrated circuit according to Embodiment 1.

FIG. 8 is a diagram illustrating a result of classification performed by the classification method for the semiconductor integrated circuit according to Embodiment 1.

FIG. 9 is a flow chart illustrating steps in a design method for a semiconductor integrated circuit according to Embodiment 1.

FIG. 10 is a block diagram illustrating the entire configuration of a design system for a semiconductor integrated circuit according to Embodiment 2.

FIG. 11 is a block diagram illustrating the functional configuration of a classification engine training device according to Embodiment 2.

FIG. 12 is a diagram illustrating an example of assignment of major ID values and first minor ID values according to Embodiment 2.

FIG. 13 is a block diagram illustrating the functional configuration of a classification engine according to Embodiment 2.

FIG. 14 is a flow chart illustrating steps in a classification engine training method for a semiconductor integrated circuit according to Embodiment 2.

FIG. 15 is a flow chart illustrating steps in a classification method for a semiconductor integrated circuit according to Embodiment 2.

FIG. 16 is a flow chart illustrating steps in a design method for a semiconductor integrated circuit according to Embodiment 2.

FIG. 17 is a first diagram illustrating an example of a design data item.

FIG. 18 is a second diagram illustrating an example of a design data item.

FIG. 19 is a diagram illustrating an example of a base design data item.

FIG. 20 is a first diagram illustrating an example of a partial design data item.

FIG. 21 is a second diagram illustrating an example of a partial design data item.

### DESCRIPTION OF EMBODIMENTS

Hereinafter, embodiments of the present disclosure are described in detail with reference to the drawings. It should be noted that each of the embodiments described below shows a specific example of the present disclosure. Numerical values, shapes, materials, standards, constituent elements, the arrangement and connection of the constituent elements, steps, order of steps, etc. shown in the following embodiments are mere examples, and are not intended to limit the present disclosure. Moreover, among the constituent elements in the following embodiments, those not recited in any of the independent claims defining the broadest concept are described as optional constituent elements. Furthermore, the respective figures are not necessarily precise illustrations. In the respectively figures, substantially identical constituent elements are given the same reference signs, and overlapping descriptions may be omitted or simplified.

### Embodiment 1

The following describes a classification engine training method for a semiconductor integrated circuit, a classification method for a semiconductor integrated circuit, a design method for a semiconductor integrated circuit, and a design system for a semiconductor integrated circuit according to Embodiment 1.

### 1-1. Design System For Semiconductor Integrated Circuit

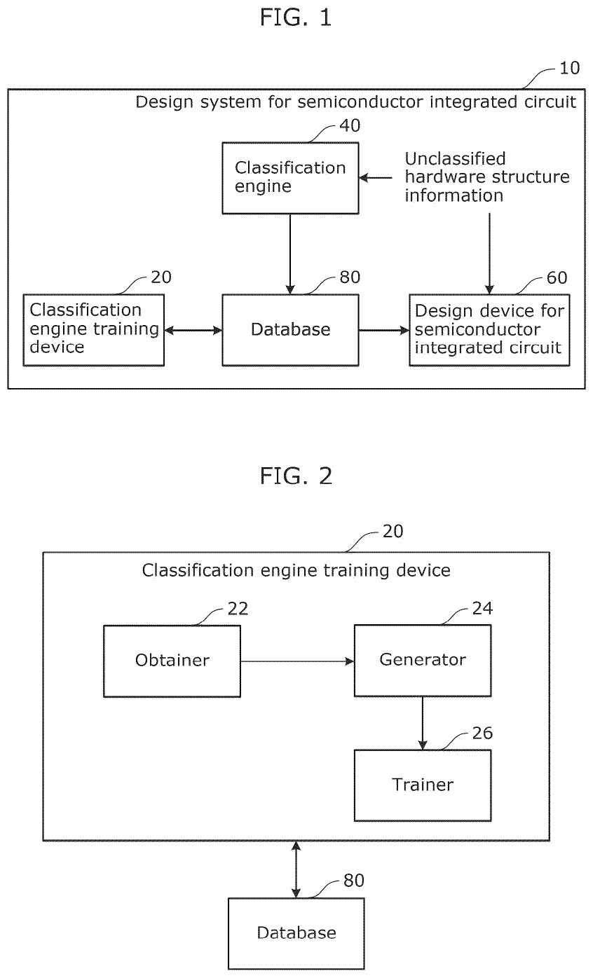

The following describes the configuration of a design system for a semiconductor integrated circuit according to the present embodiment with reference to FIG. 1. FIG. 1 is a block diagram illustrating the entire configuration of design system for semiconductor integrated circuit 10 according to the present embodiment.

Design system for semiconductor integrated circuit 10 is a system that designs a (physical) layout of a semiconductor integrated circuit, based on a hardware structure information item describing the semiconductor integrated circuit. A hardware structure information item is a structure information item in which a semiconductor integrated circuit is described in a hardware description language, and is also referred to as a hardware structure statement. Specifications such as the configuration and operation of a semiconductor integrated circuit are described in a hardware structure information item. For example, a hardware structure information item may be a gate level netlist. A hardware description language in which a hardware structure information item is described is not particularly limited. A hardware structure information item may be described, for example, at a register transfer level (RTL), at a behavior level, or in a unified modeling language (UML).

As shown in FIG. 1, design system for semiconductor integrated circuit 10 according to the present embodiment includes classification engine training device 20, classification engine 40, design device for semiconductor integrated circuit 60, and database 80.

In design system for semiconductor integrated circuit 10, a layout for an unclassified hardware structure information item is designed using design device for semiconductor integrated circuit 60 that is a layout automated design device, the unclassified hardware structure information item being a hardware structure information item for which a design information item such as a layout data item is not obtained. In design device for semiconductor integrated circuit 60, a layout is designed using a technique called a warm start. In the technique called the warm start, a layout data item serving as a base is inputted as an initial value for layout design. Hereinafter, a layout data item inputted as an initial value to design device for semiconductor integrated circuit 60 is also referred to as an initial layout data item. By using an appropriate initial layout data item in the layout design, it is possible to reduce computational resources and time in the layout design.

In the present embodiment, one or more layout data items each corresponding to a different one of one or more hardware structure information items are stored in database 80. Classification engine 40 is a neutral network trained to select an initial layout data item corresponding to an unclassified hardware structure information item, and selects, from the one or more layout data items, a layout data item corresponding to an unclassified hardware structure information item. Classification engine 40 is trained by classification engine training device 20. Hereinafter, each of the constituent elements of design system for semiconductor integrated circuit 10 is described.

Database 80 is a memory circuit in which data used in each constituent element of design system for semiconductor integrated circuit 10 according to the present embodiment is stored. In the present embodiment, database 80 stores, for example, one or more hardware structure information items, one or more major ID values, and one or more layout data items.

Classification engine training device 20 is a device that trains classification engine 40 using a classification engine training method to be described later. Classification engine training device 20 is described with reference to FIG. 2. FIG. 2 is a block diagram illustrating the functional configuration of classification engine training device 20 according to the present embodiment. FIG. 2 also shows database 80. As shown in FIG. 2, classification engine training device 20 includes obtainer 22, generator 24, and trainer 26.

Obtainer 22 is an example of a first obtainer that obtains a base design data item that is a design data item corresponding to each of the one or more hardware structure information items that describe a semiconductor integrated circuit and are different from each other. Here, a design data item is a data item corresponding to a hardware structure information item and used in layout design. Examples of the design data item include a data item in a graph object format. In the present embodiment, obtainer 22 obtains a base graph object in the graph object format as a base design data item.

A base graph object is a graph object into which a hardware structure information item has been converted. Obtainer 22 may obtain a base graph object from, for example, database 80, or may convert the one or more hardware structure information items into a base graph object. In the present embodiment, the one or more hardware structure information items are stored in database 80, and obtainer 22 converts each of the one or more hardware structure information items into a base graph object.

A base graph object may be, for example, a graph object in a control data flow graph (CDFG) format. The base graph object includes a plurality of base nodes and one or more base edges into which respective descriptions in a hardware structure information item have been converted. Each of the plurality of base nodes is a node corresponding to a hardware instance achieving a function represented by a hardware structure information item corresponding to the base graph object, the hardware structure information item being included in the one or more hardware structure information items. Each of the one or more base edges is an edge corresponding to a connector connected to the hardware instance.

In the present embodiment, the one or more hardware structure information items include a plurality of hardware structure information items. Each of the one or more hardware structure information items is a hardware structure information item that has been designed, and a layout data item of each of the one or more hardware structure information items is obtained. One major ID value is assigned to each of the one or more hardware structure information items, the one major ID value being included in the one or more major ID values different from each other. Each of the one or more major identification data (ID) values is an identification information item for identifying a corresponding one of the plurality of hardware structure information items.

In the present embodiment, one major ID value is assigned to each of the plurality of hardware structure information items, based on the plurality of hardware structure information items and a layout data item about the semiconductor integrated circuit, the one major ID value being included in a plurality of major ID values different from each other, the plurality of hardware structure information items describing the semiconductor integrated circuit and being different from each other, the layout data item being generated based on each of the plurality of hardware structure information items. The plurality of major ID values may be assigned by, for example, classification engine training device 20, or the plurality of major ID values may be stored in database 80 in a state in which the plurality of major ID values are assigned to the plurality of hardware structure information items in advance.

It should be noted that although the one or more hardware structure information items, the one or more major ID values each associated with a different one of the one or more hardware structure information items, and one or more layout metadata items are obtained from database 80 in the present embodiment, these items may be inputted to classification engine training device 20 from, for example, an input device other than database 80. Examples of the hardware instance include a gate and a register. Additionally, when hardware structure information items are described in the unified modeling language, the hardware instance includes a unit such as a central processing unit (CPU).

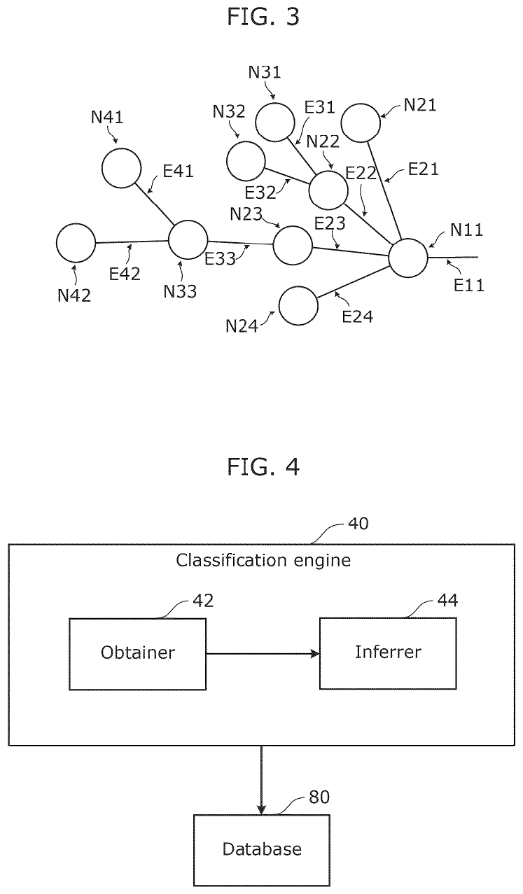

A base graph object according to the present embodiment is described with reference to FIG. 3. FIG. 3 is a diagram illustrating an example of the base graph object according to the present embodiment. In the example shown in FIG. 3, the base graph object includes base nodes N11, N21, N22, N23, N24, N31, N32, N33, N41, and N42 and base edges E11, E21, E22, E23, E24, E31, E32, E33, E41, and E42.

A plurality of base nodes include a base node corresponding to an operator, a base node performing a sequential operation, etc. The plurality of base nodes include one or more first base nodes. Each of the one or more first base nodes may have, as a feature, a degree of computational complexity in the hardware instance corresponding to the first base node. Here, for example, a complexity (order) representing the performance of computation using an algorithm is used as a computational complexity. There is a concept of a time complexity (processing time) or a space complexity (memory usage) as the complexity. An O notation is representative as a method for expressing a time complexity. O notations include, in the order of shorter processing time, O(1): constant time, O(log N): logarithmic time, O(N): linear time, O(N log N): quasilinear time or linear logarithmic time, O(N\hat{ }2): quadratic time, O(N\hat{ }3): polynomial time, O(k\hat{ }N): exponential time, and O (N!): factorial time.

Moreover, the one or more base nodes include one or more second base nodes. Each of the one or more second base nodes may have, as a feature, the number of inputs to the second base node. For example, the number of inputs to base node N11 is four, and the number of inputs to base node N22 is two.

Furthermore, the plurality of base nodes include one or more third base nodes. Each of the one or more third base nodes may have, as a feature, the number of base nodes through which an input to the third base node passes, the base nodes being included in the plurality of base nodes. For example, base nodes through which an input to base node N23 passes (i.e., series-connected nodes through which an input to base node N23 passes) are two nodes, that is, base node N33 and base node N41 (or base node N42).

Moreover, the one or more base nodes may have, as a feature, the calculation efficiency of an operator, power efficiency, etc.

The one or more base edges include one or more first base edges. Each of the one or more first base edges may have, as a feature, the amount of information transmitted by the connector corresponding to the first base edge.

Furthermore, a hardware structure information item is described in an RTL, and a connector corresponding to each of the one or more base edges may be wiring connected to the hardware instance. The wiring has a bus structure, and the amount of information transmitted by the connector corresponding to the base edge includes a bus width of the bus structure. For example, in the example shown in FIG. 3, the bus width of base edge E21 may be 4 bits. The bus width of base edge E22 may be 32 bits. The bus widths of base edges E23, E31, E32, and E33 may be 16 bits. The bus width of base edge E24 may be 2 bits. The bus widths of base edges E41 and E42 may be 8 bits.

When a hardware structure information item is a gate level netlist more similar to a layout data item than to an RTL description, in general, a technology information item, a constraint information item, etc. that are not described in the hardware structure information item are set as a premise.

Here, a technology information item is an information item that differs from semiconductor manufacturing process to semiconductor manufacturing process. A gate level netlist (for a specific manufacturing process) is closer to a layout data item (for the specific manufacturing process) than a combination of an RTL description and a technology information item (for the specific manufacturing process) is.

The technology information item may be included in the feature of a base node. This allows classification engine 40 to make inference in consideration of information relating to a manufacturing process (e.g., library information). In addition, by controlling a weight of the feature, it is possible to control the degree of consideration of a manufacturing process in inference (inference in consideration of information on a manufacturing process or inference not based on the manufacturing process (i.e., in consideration of mainly a circuit structure)).

A constraint information item includes, for example, a constraint on the operating frequency of a semiconductor integrated circuit and a constraint information item about an area. The constraint information item may be included in the feature of a base node. This allows classification engine 40 to make inference in consideration of the constraint information item. In addition, by controlling a weight of the feature, it is possible to control the degree of consideration of the constraint information item in inference (inference in consideration of the constraint information item or inference not based on the constraint information item (i.e., in consideration of mainly a circuit structure)).

By embedding, as a feature, an index relating to a physical metrics of the semiconductor integrated circuit into a neural network included in classification engine 40 as above, it is possible to train the neural network based on more information. As stated above, the neural network according to the present embodiment is a graph neutral network. In the graph neural network, although convolution in consideration of a connection relation among nodes is performed, by adding, as a feature, collateral information other than the connection relation to the graph neural network, it is possible to perform training about the characteristics of a graph object to be learned, using more information. Consequently, it is possible to improve the accuracy of inference made by the neural network.

Moreover, each of the plurality of base nodes may have, as a feature, the degree of disadvantage in computation such as a calculation cost of a node corresponding to an operator and/or a complexity of computation. Furthermore, each of a plurality of first nodes may have, as a feature, the degree of advantage in computation such as the calculation efficiency and/or power efficiency of a node corresponding to an operator. Accordingly, by embedding, as a feature, an index relating to a physical metrics of the semiconductor integrated circuit into the neural network, training based on more information is made possible. Consequently, it is possible to improve the accuracy of inference made by the neural network. Moreover, by the base node having the degree of disadvantage in computation as the feature, it is possible to treat the degree of disadvantage in computation as the degree of importance of a design problem. Furthermore, by the first node having the degree of advantage in computation as the feature, it is possible to treat the degree of advantage in computation as the degree of importance that serves as a trade-off with the degree of disadvantage in computation.

Generator 24 shown in FIG. 2 is a processor that generates a training design data set including a plurality of additional design data items, based on a base design data item. The plurality of additional design data items may be stored in, for example, generator 24 or database 80. The plurality of additional design data items are different from each other, and each includes a partial base graph object that is a portion of the base design data item and different from the base design data item. It should be noted that the plurality of additional design data items may include the base design data item.

In the present embodiment, generator 24 generates, based on a base graph object, a training design data set including a plurality of additional graph objects in a graph object format as a plurality of additional design data items. The plurality of additional graph objects are different from each other, and each includes, as a partial base design data item, a partial base graph object that is a portion of the base graph object and different from the base graph object. It should be noted that the plurality of additional graph objects may include the base graph object.

A partial base graph object includes a plurality of partial nodes. The number of the plurality of partial nodes may be greater than half the number of a plurality of base nodes. For example, of the base graph object shown in FIG. 3, a graph object including base nodes N11, N23, N24, N33, N41, and N42 and base edges E11, E23, E24, E33, E41, and E42 may be a partial base graph object. In this case, base nodes N11, N23, N24, N33, N41, and N42 correspond to a plurality of partial nodes included in a partial base graph object, and base edges E11, E23, E24, E33, E41, and E42 correspond to one or more partial edges included in the partial base graph object. By generating the partial base graph object as above, it is possible to generate the partial base graph object that is similar to the base graph object and different from the base graph object.

A plurality of additional graph objects may include a combined graph object that is a combination of a partial base graph object and a noise graph object. Although the configuration of the noise graph object is not particularly limited, the number of nodes included in the noise graph object may be less than the number of partial nodes included in the partial base graph object. By generating the plurality of additional graph objects as above, it is possible to generate a large number of graph objects that are similar to a base graph object and different from the base graph object.

Generator 24 shown in FIG. 2 may generate a partial base graph object, based on features of a plurality of base nodes included in a base graph object. For example, generator 24 may classify the plurality of base nodes into a plurality of groups including a first group and a second group, based on first features of the plurality of base nodes. A plurality of partial nodes included in the partial base graph object generated by generator 24 may include, among the plurality of base nodes included in the base graph object, a base node included in the first group and a base node included in the second group. Here, a range of first features corresponding to the first group may include a representative value of the first features of the plurality of base nodes. The representative value of the first features of the plurality of base nodes may be, for example, a median, a mean, or a mode of the first features of the plurality of base nodes.

For example, the following describes a case in which, in the example shown in FIG. 3, the number of inputs to a base node is used as a first feature, and a mode is used as a representative value. As shown in FIG. 3, since the number of inputs in base nodes N21, N23, N24, N31, N32, N41, and N42 is 1, the number of inputs in base nodes N22 and N33 is 2, and the number of inputs in base node N11 is 4, the mode of the numbers of the inputs that are first features is 1. In view of this, a value of a first feature corresponding to the first group is set to 1, and a value of a first feature corresponding to the second group is set to, for example, 2. In this case, the partial nodes included in the partial base graph object may include at least one of base nodes N21, N23, N24, N31, N32, N41, and N42 included in the first group, and at least one of base nodes N22 and N33 included in the second group. By generating the partial base graph object as above, it is possible to reduce an imbalance in feature in the partial base graph object. Accordingly, it is possible to generate the partial base graph object similar to the base graph object.

Moreover, the partial base graph object may be generated by sampling a portion of the base graph object using a publicly known sampling method as disclosed in, for example, NPL 1.

Trainer 26 shown in FIG. 2 is a processor that trains a neural network using, as an input, each of the plurality of additional design data items generated by generator 24. The neural network trained by trainer 26 is used in classification engine 40. The neural network classifies unclassified hardware structure information items in classification engine 40. In the present embodiment, the neural network is a graph neural network.

Trainer 26 trains the neural network using, as an input, each of the plurality of additional design data items, to infer one major ID value corresponding to the additional design data item to be used as the input, the one major ID value corresponding to the additional design data item being included in one or more major ID values.

In the present embodiment, trainer 26 trains the neural network using, as an input, each of a plurality of additional graph objects as a plurality of additional data items. Trainer 26 trains the neural network using, as an input, each of the plurality of additional graph objects, to infer one major ID value corresponding to the additional graph object to be used as the input, the one major ID value corresponding to the additional graph object being included in the one or more major ID values. In other words, when a plurality of additional graph objects generated based on one hardware structure information item are inputs for the neural network, trainer 26 trains the neural network to infer one major ID value corresponding to the one hardware structure information item. To put it another way, trainer 26 trains the neural network to classify the plurality of additional graph objects into one group represented by a corresponding one base graph object. Such classification means that when layout design of the plurality of additional graph objects classified into the one group is performed by design device for semiconductor integrated circuit 60, it is possible to use, as an initial layout data item, a layout data item corresponding to the one base graph object.

In the present embodiment, since the plurality of additional design data items are used as the inputs in the training of the neural network, it is possible to improve the accuracy of inference made by the neural network compared to a case in which only base design data items are used as inputs.

Furthermore, since each of the plurality of additional design data items includes a partial base design data item that is a portion of a base design data item, the additional design data item is similar to the base design data item. For this reason, by using, as an initial layout data item, a layout data item corresponding to the base design data item when a layout of each of the plurality of additional design data items is designed by design device for semiconductor integrated circuit 60, it is possible to reduce computation resources and time necessary for design.

Classification engine 40 shown in FIG. 1 is an engine that classifies an unclassified hardware structure information item using a neural network trained by classification engine training device 20. Classification engine 40 according to the present embodiment is described with reference to FIG. 4. FIG. 4 is a block diagram illustrating the functional configuration of classification engine 40 according to the present embodiment. FIG. 4 also shows database 80. As shown in FIG. 4, classification engine 40 includes obtainer 42 and inferrer 44.

Obtainer 42 is an example of a second obtainer that obtains an unclassified base design data item corresponding to an unclassified hardware structure information item different from one or more hardware structure information items (a plurality of hardware structure information items in the present embodiment). In the present embodiment, obtainer 42 obtains, as an unclassified base design data item, an unclassified base graph object in a graph object format. An unclassified base graph object is a graph object into which an unclassified hardware structure information item has been converted. Obtainer 42 may obtain an unclassified base graph object from, for example, database 80, or may convert an unclassified hardware structure information item into an unclassified base graph object. In the present embodiment, an unclassified hardware structure information item is inputted to classification engine 40, and obtainer 42 converts the unclassified hardware structure information item into an unclassified base graph object. The unclassified base graph object may be, for example, a graph object in the CDFG format.

Inferrer 44 includes the neural network trained by classification engine training device 20. By inputting unclassified base design data items to the trained neutral network, inferrer 44 infers one major ID value corresponding to an unclassified base design data item, the one major ID value corresponding to the unclassified base design data item being included in the one or more major ID values. In the present embodiment, the one or more hardware structure information items include a plurality of hardware structure information items. For this reason, the unclassified base design data item is classified into a group corresponding to the major ID value inferred. In other words, it is inferred that when layout design of the unclassified hardware structure information item is performed by design device for semiconductor integrated circuit 60, it is possible to use, as an initial layout data item, a layout data item corresponding to a hardware structure information item to which the major ID value is assigned. In the present embodiment, by inputting unclassified base graph objects to the trained neutral network, inferrer 44 infers one major ID value corresponding to an unclassified base graph object, the one major ID value corresponding to the unclassified base graph object being included in the one or more major ID values.

Design device for semiconductor integrated circuit 60 shown in FIG. 1 generates a layout data item which is based on an unclassified hardware structure information item, based on one hardware structure information item to which one major ID value inferred by classification engine 40 has been assigned, and a design data item relating to a layout data item generated based on the one hardware structure information item, the one hardware structure information item being included in the plurality of hardware structure information items.

In the present embodiment, an unclassified hardware structure information item is inputted to design device for semiconductor integrated circuit 60, and design device for semiconductor integrated circuit 60 generates a layout data item which is based on the unclassified hardware structure information item.

It is possible to use, as design device for semiconductor integrated circuit 60, any EDA tool that is for automating design of a layout corresponding to a hardware structure information item and is compatible with a warm start.

Design device for semiconductor integrated circuit 60 obtains, from database 80, an initial layout data item, based on the one major ID value inferred. The initial layout data item includes a design data item relating to a layout data item corresponding to a hardware structure information item to which the one major ID value inferred is assigned. The initial layout data item may include a layout metadata item obtained by combining the design data item with a metadata item corresponding to a major ID value. The layout metadata item may include, for example, a layout constraint and a layout script.

As stated above, by classifying the unclassified hardware structure information item appropriately using classification engine 40 including the neural network trained by classification engine training device 20, it is possible to select the initial layout data item suitable for the unclassified hardware structure information item. Accordingly, by design device for semiconductor integrated circuit 60 performing the layout design using the initial layout data item selected, it is possible to reduce computational resources and time.

### 1-2. Hardware Configuration

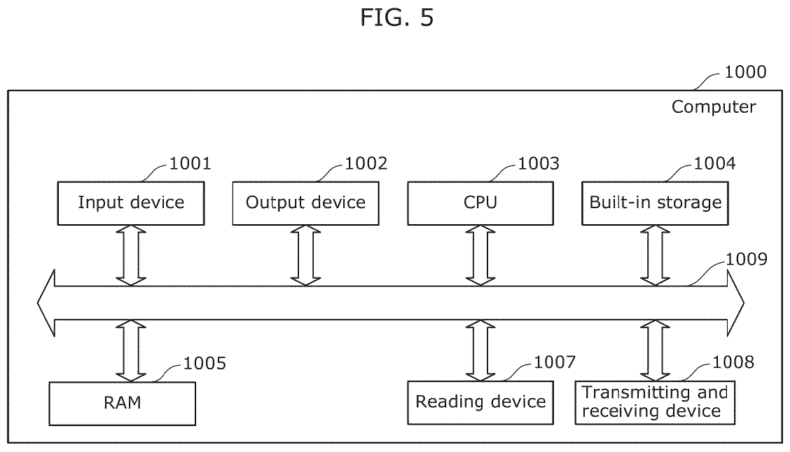

Next, the hardware configuration of design system for semiconductor integrated circuit 10 according to the present embodiment is described with reference to FIG. 5. FIG. 5 is a diagram illustrating an example of the hardware configuration of computer 1000 that implements the functions of design system for semiconductor integrated circuit 10 according to the present embodiment, using software.

As shown in FIG. 5, computer 1000 includes input device 1001, output device 1002, CPU 1003, built-in storage 1004, RAM 1005, reading device 1007, transmitting and receiving device 1008, and bus 1009. Input device 1001, output device 1002, CPU 1003, built-in storage 1004, RAM 1005, reading device 1007, and transmitting and receiving device 1008 are connected by bus 1009.

Input device 1001 is a device that serves as a user interface such as an input button, a touchpad, or a touch panel display, and receives an operation from a user. It should be noted that input device 1001 may be configured to receive an operation by audio or a remote operation by a remote controller etc., in addition to receiving a touch operation from the user.

Output device 1002 is a device that outputs signals from computer 1000, and may be a device that serves as a user interface such as a display or a loudspeaker, in addition to a signal output terminal.

Built-in storage 1004 is, for example, flash memory. Moreover, in addition to data of design system for semiconductor integrated circuit 10 stored in database 80, at least one of a program for implementing the functions of design system for semiconductor integrated circuit 10 or an application using the functional configuration of design system for semiconductor integrated circuit 10 may be stored in built-in storage 1004 in advance.

RAM 1005 is random-access memory, and is used to store data etc. when a program or an application is executed.

Reading device 1007 reads information from a recording medium such as universal serial bus (USB) memory. Reading device 1007 reads the program or the application as described above from a recording medium on which the program or the application is recorded, and stores the program or the application in built-in storage 1004.

Transmitting and receiving device 1008 is a communication circuit for performing wireless or wired communication. Transmitting and receiving device 1008 communicates with, for example, a server device connected to a network, and may download the program or the application as described above from the server device and store the program or the application in built-in storage 1004.

CPU 1003 is a central processing unit, copies, for example, a program or an application stored in built-in storage 1004 to RAM 1005, sequentially reads, from RAM 1005, instructions included in, for example, the program or the application copied, and executes the instructions.

### 1-3. Classification Engine Training Method for Semiconductor Integrated Circuit

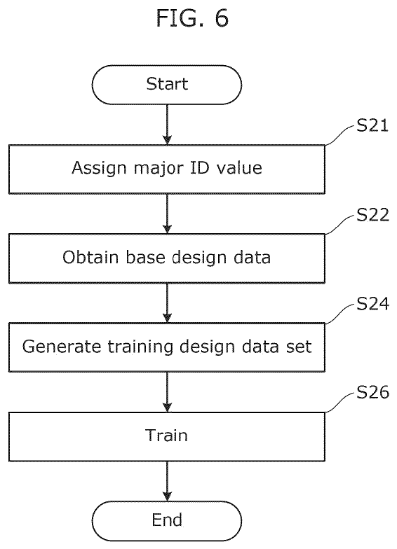

A classification engine training method for a semiconductor integrated circuit according to the present embodiment is described with reference to FIG. 6. FIG. 6 is a flow chart illustrating steps in the classification engine training method for the semiconductor integrated circuit according to the present embodiment. The classification engine training method for the semiconductor integrated circuit according to the present embodiment is performed by classification engine training device 20.

As shown in FIG. 6, first, one major ID value is assigned to each of one or more hardware structure information items, based on the one or more hardware structure information items and a layout data item about the semiconductor integrated circuit, the one major ID value being included in one or more major ID values different from each other, the one or more hardware structure information items describing the semiconductor integrated circuit and being different from each other, the layout data being generated based on each of the one or more hardware structure information items (first assignment step S21). In the present embodiment, the one or more hardware structure information items include a plurality of hardware structure information items. Each of the one or more hardware structure information items may be a gate level netlist.

Next, obtainer 22 of classification engine training device 20 obtains a base design data item corresponding to each of the one or more hardware structure information items (base design data obtainment step S22). In the present embodiment, obtainer 22 obtains, as a base design data item, a base graph object in a graph object format in base design data obtainment step S22. The base graph object includes a plurality of base nodes and one or more base edges into which respective descriptions in a hardware structure information item have been converted. The plurality of base nodes include a base node corresponding to an operator, a base node performing a sequential operation, etc. The plurality of base nodes include one or more first base nodes. Each of the one or more first base nodes may have, as a feature, a degree of computational complexity in a hardware instance corresponding to the first base node.

Moreover, the one or more base nodes include one or more second base nodes. Each of the one or more second base nodes may have, as a feature, the number of inputs to the second base node.

Furthermore, the plurality of base nodes include one or more third base nodes. Each of the one or more third base nodes may have, as a feature, the number of base nodes through which an input to the third base node passes, the base nodes being included in the plurality of base nodes.

The one or more base edges include one or more first base edges. Each of the one or more first base edges may have, as a feature, the amount of information transmitted by a connector corresponding to the first base edge.

Then, generator 24 of classification engine training device 20 generates a training design date set including a plurality of additional design data items, based on the base design data item obtained in base design data obtainment step S22 (generation step S24). The plurality of additional design data items are different from each other, and each includes a partial base design data item that is a portion of the base design data item and different from the base design data item.

In the present embodiment, generator 24 generates a training design data set including, as a plurality of additional design data items, a plurality of additional graph objects in the graph object format in generation step S24. The plurality of additional graph objects are different from each other, and each includes, as a partial base design data item, a partial base graph object that is a portion of the base graph object and different from the base graph object. The partial base graph object includes a plurality of partial nodes. The number of the plurality of partial nodes may be greater than half the number of the plurality of base nodes.

The plurality of additional graph objects may include a combined graph object that is a combination of a partial base graph object and a noise graph object. The number of nodes included in the noise graph object may be less than the number of partial nodes included in the partial base graph object.

Generator 24 may generate a partial base graph object, based on features of a plurality of base nodes included in a base graph object in generation step S24. Generator 24 may classify the plurality of base nodes into a plurality of groups including a first group and a second group, based on first features of the plurality of base nodes in generation step S24. A plurality of partial nodes included in the partial base graph object generated by generator 24 may include, among the plurality of base nodes included in the base graph object, a base node included in the first group and a base node included in the second group. Here, a range of first features corresponding to the first group may include a representative value of the first features. The representative value of the first features may be, for example, a median, a mean, or a mode of the first features.

Next, trainer 26 of classification engine training device 20 trains a neural network using, as an input, each of the plurality of additional design data items (training step S26). In training step S26, trainer 26 trains the neural network using, as an input, each of the plurality of additional design data items, to infer one major ID value corresponding to the additional design data item to be used as the input, the one major ID value corresponding to the additional design data item being included in one or more major ID values. In the present embodiment, trainer 26 trains the neural network using, as an input, each of the plurality of additional graph objects as the plurality of additional design data items in training step S26. In training step S26, trainer 26 trains the neural network using, as an input, each of the plurality of additional graph objects, to infer one major ID value corresponding to the additional graph object, the one major ID value corresponding to the additional graph object being included in the one or more major ID values.

As stated above, by training the neural network using the plurality of additional design data items, the neural network is capable of making inference with higher accuracy than when the neural network is trained using only a base design data item.

### 1-4. Classification Method for Semiconductor Integrated Circuit

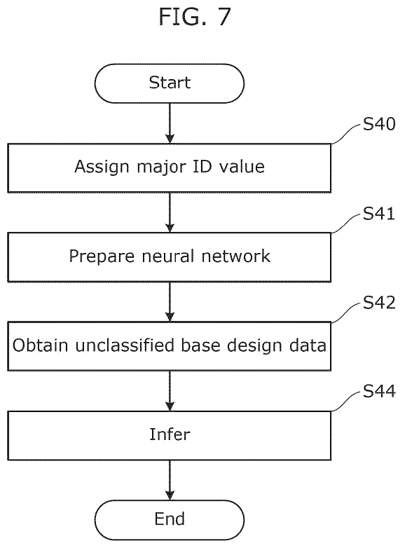

A classification method for a semiconductor integrated circuit according to the present embodiment is described with reference to FIG. 7. FIG. 7 is a flow chart illustrating steps in the classification method for the semiconductor integrated circuit according to the present embodiment. The classification method for the semiconductor integrated circuit according to the present embodiment is performed by classification engine 40.

As shown in FIG. 7, first, as with the classification engine training method, one major ID value is assigned to each of one or more hardware structure information items, based on the one or more hardware structure information items and a layout data item about the semiconductor integrated circuit, the one major ID value being included in one or more major ID values different from each other, the one or more hardware structure information items describing the semiconductor integrated circuit and being different from each other, the layout data being generated based on each of the one or more hardware structure information items (first assignment step S40).

Next, a neural network trained by the above-described classification engine training method for the semiconductor integrated circuit is prepared (preparation step S41). In the present embodiment, a neural network is trained by classification engine training device 20.

Next, obtainer 42 of classification engine 40 obtains an unclassified base design data item corresponding to an unclassified hardware structure information item different from a plurality of hardware structure information items (unclassified base design data obtainment step S42). In the present embodiment, obtainer 42 obtains, as an unclassified base design data item, an unclassified base graph object in a graph object format in unclassified base design data obtainment step S42.

In unclassified base design data obtainment step S42, obtainer 42 may obtain an unclassified base design data item from, for example, database 80, or may convert an unclassified hardware structure information item into an unclassified base design data item. In the present embodiment, an unclassified hardware structure information item is inputted to classification engine 40, and obtainer 42 converts the unclassified hardware structure information item into an unclassified base graph object as an unclassified base design data item in unclassified base design data obtainment step S42.

Then, by inputting unclassified base design data items to the trained neutral network, inferrer 44 of classification engine 40 infers one major ID value corresponding to an unclassified base design data item, the one major ID value corresponding to the unclassified base design data item being included in the one or more major ID values (inference step S44). In the present embodiment, in inference step S44, by inputting unclassified base graph objects as the unclassified base design data items to the trained neutral network, inferrer 44 infers the one major ID value corresponding to an unclassified base graph object, the one major ID value corresponding to the unclassified base graph object being included in the one or more major ID values.

For this reason, the unclassified base design data item is classified into a group corresponding to the major ID value inferred. In other words, it is inferred that when layout design of the unclassified hardware structure information item is performed by design device for semiconductor integrated circuit 60, it is possible to use, as an initial layout data item, a layout data item corresponding to a hardware structure information item to which the major ID value is assigned.

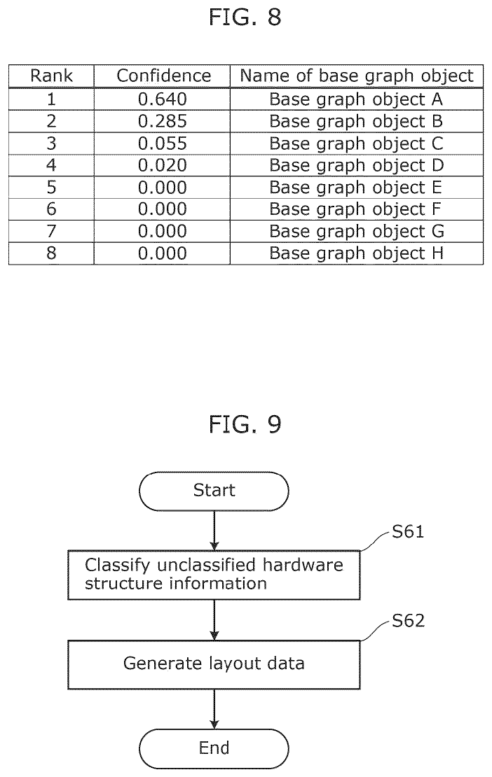

The following describes the results of verifying the classification method for the semiconductor integrated circuit according to the present embodiment. In the verifications, a neural network trained by a classification engine training method was prepared using eight base graph objects A to H different from each other. An unclassified base graph object was generated by adding, to base graph object A, a noise graph object having approximately 40 percent of the amount of entire base graph object A. The results of classifying such an unclassified base graph object using the classification method for the semiconductor integrated circuit according to the present embodiment are described with reference to FIG. 8. FIG. 8 is a diagram illustrating a result of classification performed by the classification method for the semiconductor integrated circuit according to the present embodiment. In FIG. 8, base graph objects A to H are shown in the order of confidence about a base graph object. A confidence shown in FIG. 8 is a value indicating the degree of confidence in being classified as a corresponding base graph object. A confidence is represented by a value of at least 0 and at most 1, and has a higher degree of confidence with an increase in value.

An unclassified base graph object obtained by altering base graph object A is similar to base graph object A but different from base graph object A. Such an unclassified base graph object is classified as base graph object A, based on a confidence shown in FIG. 8. As described above, the classification method for the semiconductor integrated circuit according to the present embodiment makes it possible to classify an unclassified base graph object appropriately.

### 1-5. Design Method for Semiconductor Integrated Circuit

A design method for a semiconductor integrated circuit according to the present embodiment is described with reference to FIG. 9. FIG. 9 is a flow chart illustrating steps in the design method for the semiconductor integrated circuit according to the present embodiment. The design method for the semiconductor integrated circuit according to the present embodiment is performed by classification engine 40 and design device for semiconductor integrated circuit 60.

As shown in FIG. 9, first, an unclassified hardware structure information item is classified by inferring one major ID value using the above-described classification method for the semiconductor integrated circuit (classification step S61).

Next, a layout data item which is based on the unclassified hardware structure information item is generated based on one hardware structure information item to which one major ID value is assigned, and a design data item relating to a layout data item generated based on the one hardware structure information item, the one hardware structure information item being included in a plurality of hardware structure information items (layout data generation step S62). In layout data generation step S62, for example, layout design is performed by design device for semiconductor integrated circuit 60 using, as an initial layout data item, a layout data item generated based on a hardware structure information item to which the one major ID value inferred in classification step S61 is assigned. The initial layout data item may include a layout metadata item obtained by combining the design data item with a metadata item corresponding to a major ID value. The layout metadata item may include, for example, a layout constraint and a layout script.

As stated above, by classifying the unclassified hardware structure information item appropriately using classification engine 40 including the neural network trained by classification engine training device 20, it is possible to select the initial layout data item suitable for the unclassified hardware structure information item. Accordingly, by design device for semiconductor integrated circuit 60 performing the layout design using the initial layout data item selected, it is possible to reduce computational resources and time.

### Embodiment 2

The following describes a classification engine training method for a semiconductor integrated circuit, a classification method for a semiconductor integrated circuit, a design method for a semiconductor integrated circuit, and a design system for a semiconductor integrated circuit according to Embodiment 2. The classification engine training method for the semiconductor integrated circuit etc. according to the present embodiment differ from the classification engine training method for the semiconductor integrated circuit etc. according to Embodiment 1 in using not only a major ID value but also a minor ID value based on a classification result obtained from a predetermined viewpoint. Hereinafter, the classification engine training method for the semiconductor integrated circuit etc. according to the present embodiment are described by focusing mainly on differences from the classification engine training method for the semiconductor integrated circuit etc. according to Embodiment 1.

### 2-1. Design System For Semiconductor Integrated Circuit

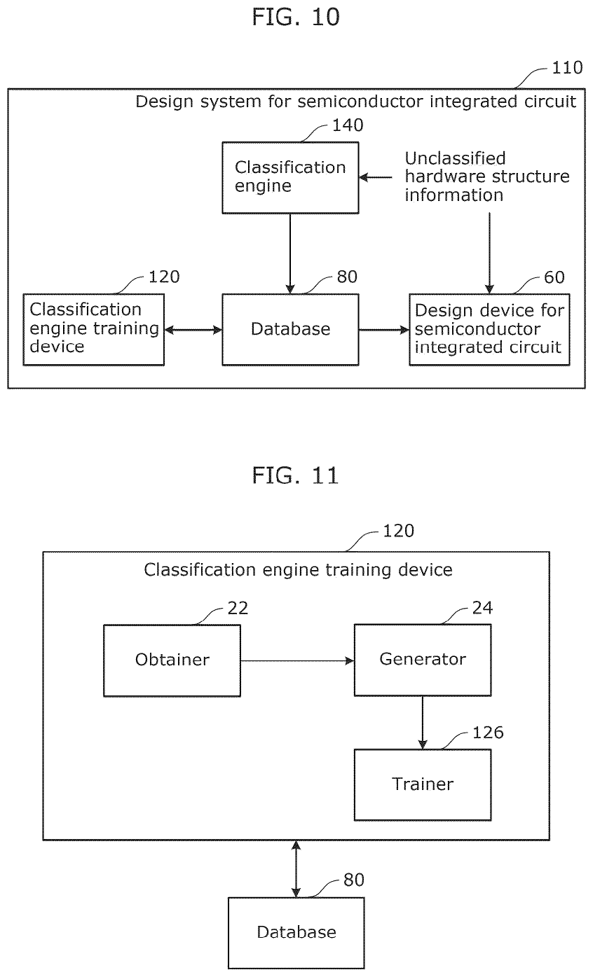

The following describes the configuration of a design system for a semiconductor integrated circuit according to the present embodiment with reference to FIG. 10. FIG. 10 is a block diagram illustrating the entire configuration of design system for semiconductor integrated circuit 110 according to the present embodiment.

As shown in FIG. 10, design system for semiconductor integrated circuit 110 according to the present embodiment includes classification engine training device 120, classification engine 140, design device for semiconductor integrated circuit 60, and database 80.

Classification engine training device 120 according to the present embodiment is described with reference to FIG. 11. FIG. 11 is a block diagram illustrating the functional configuration of classification engine training device 120 according to the present embodiment. FIG. 11 also shows database 80. As shown in FIG. 11, classification engine training device 120 includes obtainer 22, generator 24, and trainer 126.

Trainer 126 according to the present embodiment is a processor that trains a neural network using, as an input, a plurality of additional design data items generated by generator 24, in the same manner as trainer 26 according to Embodiment 1. In the present embodiment, trainer 126 trains a neural network using, as an input, each of a plurality of additional graph objects generated as the plurality of additional design data items by generator 24, in the same manner as trainer 26 according to Embodiment 1.

In the present embodiment, a first minor ID value based on a classification result obtained from a first viewpoint is assigned to each of the plurality of additional design data items each of which corresponds to a different one of a plurality of hardware structure information items. Moreover, in the present embodiment, the first minor ID value based on the classification result obtained from the first viewpoint is assigned to each of the plurality of additional graph objects each of which corresponds to a different one of the plurality of hardware structure information items. The first minor ID value based on the classification result obtained from the first viewpoint may be assigned to each of the plurality of hardware structure information items. In the present embodiment, trainer 126 assigns the first minor ID value to each of the plurality of additional graph objects.

Trainer 126 trains the neural network to infer, in addition to a major ID value, a first minor ID value corresponding to an additional design data item used as an input to the neural network, the additional design data item being included in the plurality of additional design data items. It should be noted that trainer 126 may train the neural network to infer, in addition to a major ID value, a first minor ID value corresponding to a hardware structure information item used as an input to the neural network, the hardware structure information item being included in the plurality of hardware structure information items. In the present embodiment, trainer 126 trains the neural network to infer, in addition to a major ID value, a first minor ID value corresponding to an additional graph object used as an input to the neural network, the additional graph object being included in the plurality of additional graph objects.

For example, each of the plurality of additional graph objects includes a plurality of additional nodes and one or more additional edges, and the first viewpoint may relate to features of the plurality of additional nodes and one or more features of the one or more additional edges. It should be noted that the first viewpoint is not limited to this example. For example, the first viewpoint may relate to a circuit size, the number of flip-flops, or the length of a critical path of an additional graph object or a base graph object.

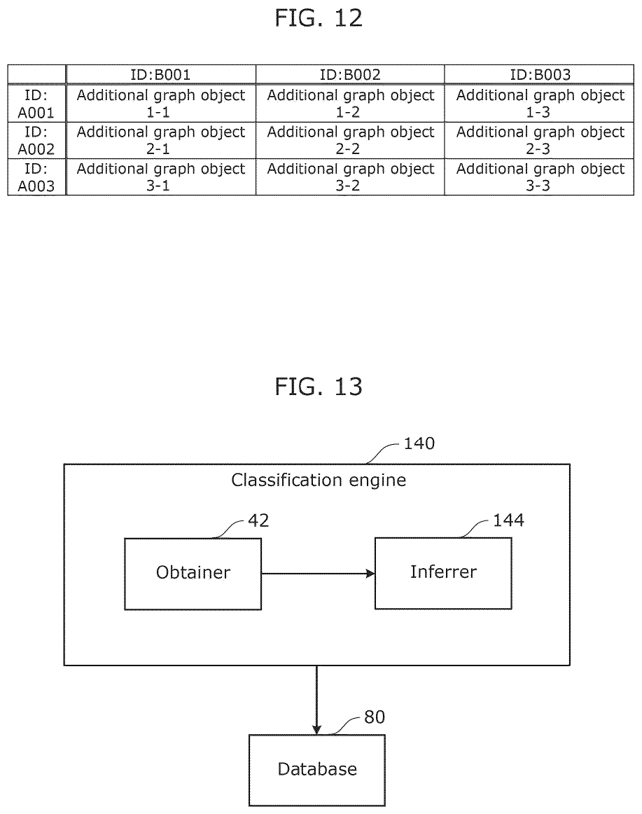

Here, major ID values and first minor ID values are described with reference to FIG. 12. FIG. 12 is a diagram illustrating an example of assignment of major ID values and first minor ID values according to the present embodiment.

Among the ID values shown in FIG. 12, A001, A002, and A003 are major ID values, and B001, B002, and B003 are first minor ID values. In FIG. 12, the first minor ID values are assigned to: additional graph objects 1-1, 1-2, and 1-3 generated based on a base graph object to which A001 is assigned as a major ID value; additional graph objects 2-1, 2-2, and 2-3 generated based on a base graph object to which A002 is assigned as a major ID value; and additional graph objects 3-1, 3-2, and 3-3 generated based on a base graph object to which A003 is assigned as a major ID value. B001 is assigned as a first minor ID value to additional graph objects 1-1, 2-1, and 3-1, B002 is assigned as a first minor ID value to additional graph objects 1-2, 2-2, and 3-2, and B003 is assigned as a first minor ID value to additional graph objects 1-3, 2-3, and 3-3. In this manner, not only a major ID value but also a minor ID value based on an other viewpoint are assigned to each additional graph object. This enables classification with a focus on characteristics common to additional graph objects based on a plurality of base graph objects, in addition to classification with a focus on characteristics of base graph objects based on major ID values.

Furthermore, a second minor ID value based on a classification result obtained from a second viewpoint may be assigned to each of the plurality of additional design data items each of which corresponds to a different one of the plurality of hardware structure information items, the second viewpoint being different from the first viewpoint. Trainer 126 may assign the second minor ID value to each of the plurality of additional design data items.

Trainer 126 may train the neural network to infer a second minor ID value corresponding to an additional design data item used as an input to the neural network, the additional design data item being included in the plurality of additional design data items. This also further enables classification with a focus on different characteristics.

It should be noted that three or more minor ID values based on a classification result obtained from three or more viewpoints are assigned, and the neural network may be trained to infer the three or more minor ID values in the present embodiment.

Classification engine 140 according to the present embodiment shown in FIG. 10 is described with reference to FIG. 13. FIG. 13 is a block diagram illustrating the functional configuration of classification engine training device 140 according to the present embodiment. As shown in FIG. 13, classification engine 140 includes obtainer 42 and inferrer 144. FIG. 13 also shows database 80.

Inferrer 144 according to the present embodiment includes a neural network trained by the classification engine training method, in the same manner as inferrer 44 according to Embodiment 1. In the present embodiment, by inputting unclassified base design data items to the trained neural network, inferrer 144 infers one major ID value corresponding to an unclassified base design data item, and a first minor ID value corresponding to the unclassified base design data item, the one major ID value corresponding to the unclassified base design data item being included in one or more major ID values. Inferrer 144 may infer a major ID value and a first minor ID value that correspond to an unclassified hardware structure information item. In the present embodiment, by inputting unclassified base graph objects to the trained neutral network, inferrer 144 infers one major ID value corresponding to an unclassified base graph object, and a first minor ID value corresponding to the unclassified base graph object, the one major ID value corresponding to the unclassified base graph object being included in the one or more major ID values.

Classification engine 140 including such inferrer 144 enables classification with a focus on characteristics common to additional design data items based on a plurality of base design data items, in addition to classification with a focus on characteristics of base design data items based on major ID values.

Inferrer 144 may infer a second minor ID value corresponding to an unclassified base design data item. For example, inferrer 144 may infer a second minor ID value corresponding to an unclassified base graph object. This also further enables classification with a focus on different characteristics. It should be noted that inferrer 144 may infer three or more minor ID values based on a classification result obtained from three or more viewpoints.

Design system for semiconductor integrated circuit 110 including classification engine training device 120 and classification engine 140 as described above allows an initial layout data item used in design device for semiconductor integrated circuit 60 to include a layout metadata item including, for example, a first minor ID value inferred by classification engine 140. As a result, design device for semiconductor integrated circuit 60 is capable of performing layout design, based on a more detailed layout constraint and a more detailed layout script. Accordingly, it is possible to reduce much more computational resources and time, and improve layout quality.

### 2-2. Classification Engine Training Method for Semiconductor Integrated Circuit

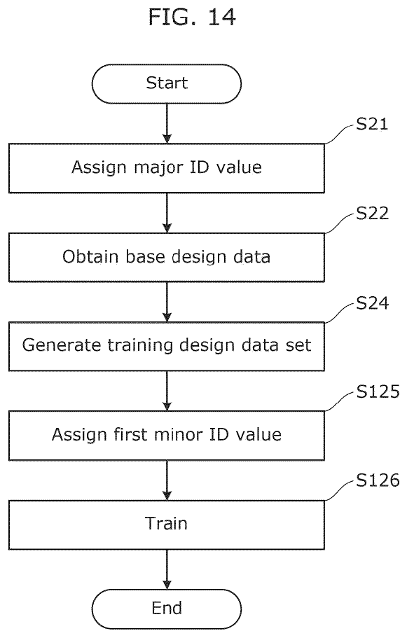

A classification engine training method for a semiconductor integrated circuit according to the present embodiment is described with reference to FIG. 14. FIG. 14 is a flow chart illustrating steps in the classification engine training method for the semiconductor integrated circuit according to the present embodiment. The classification engine training method for the semiconductor integrated circuit according to the present embodiment is performed by classification engine training device 120.

First, first assignment step S21, base design data obtainment step S22, and generation step S24 are performed in the same manner as the classification engine training method for the semiconductor integrated circuit according to Embodiment 1.

Next, a first minor ID value based on a classification result obtained from the first viewpoint is assigned to each of a plurality of additional design data items each of which corresponds to a different one of a plurality of hardware structure information items (second assignment step S125). In the present embodiment, in second assignment step S125, trainer 126 of classification engine training device 120 assigns the first minor ID value based on the classification result obtained from the first viewpoint to each of a plurality of additional graph objects each of which corresponds to a different one of the plurality of hardware structure information items.

Then, trainer 126 trains a neural network using, as an input, each of the plurality of additional design data items, in the same manner as trainer 26 of classification engine training device 20 according to Embodiment 1 (training step S126). In training step S126, trainer 126 trains the neural network using, as an input, each of the plurality of additional design data items, to infer one major ID value corresponding to the additional design data item to be used as the input, the one major ID value corresponding to the additional design data item being included in one or more major ID values. In training step S126, trainer 126 further trains the neural network to infer a first minor ID value corresponding to an additional design data item used as an input to the neural network, the additional design data item being included in the plurality of additional design data items.

In the present embodiment, trainer 126 trains the neural network using, as an input, each of the plurality of additional graph objects in training step S126. In training step S126, trainer 126 further trains the neural network to infer a first minor ID value corresponding to an additional graph object used as an input to the neural network, the additional graph object being included in the plurality of additional design data items.

Trainer 126 may train the neural network to infer, in addition to a major ID value, a first minor ID value corresponding to a hardware structure information item used as an input to the neural network, the hardware structure information item being included in the plurality of hardware structure information items.

In training step S126, trainer 126 may train the neural network to infer a second minor ID value corresponding to an additional design data item used as an input to the neural network, the additional design data item being included in the plurality of additional graph objects. This also further enables classification with a focus on different characteristics.

It should be noted that three or more minor ID values based on a classification result obtained from three or more viewpoints are assigned, and the neural network may be trained to infer the three or more minor ID values in the present embodiment. The classification engine training method for the semiconductor integrated circuit according to the present embodiment enables classification with a focus on characteristics common to additional graph objects based on a plurality of base design data items, in addition to classification with a focus on characteristics of base design data items based on major ID values.

### 2-3. Classification Method for Semiconductor Integrated Circuit

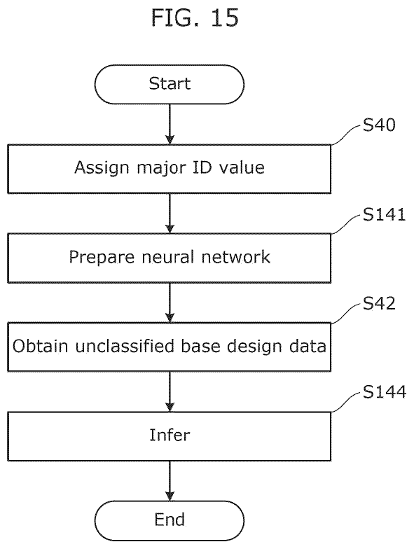

A classification method for a semiconductor integrated circuit according to the present embodiment is described with reference to FIG. 15. FIG. 15 is a flow chart illustrating steps in the classification method for the semiconductor integrated circuit according to the present embodiment. The classification method for the semiconductor integrated circuit according to the present embodiment is performed by classification engine 140.

As shown in FIG. 15, first, first assignment step S40 is performed in the same manner as the classification method for the semiconductor integrated circuit according to Embodiment 1.

Next, a neural network trained by the above-described classification engine training method for the semiconductor integrated circuit according to the present embodiment is prepared (preparation step S141). In the present embodiment, the neural network is trained by classification engine training device 120.

Then, unclassified base design data obtainment step S42 is performed in the same manner as the classification method for the semiconductor integrated circuit according to Embodiment 1.

After that, by inputting unclassified base design data items to the trained neural network, inferrer 144 of classification engine 140 infers one major ID value corresponding to an unclassified base design data item, and a first minor ID value corresponding to the unclassified base design data item, the one major ID value corresponding to the unclassified base design data item being included in one or more major ID values (inference step S144). In the present embodiment, in inference step S144, by inputting unclassified base graph objects to the trained neutral network, inferrer 144 infers one major ID value corresponding to an unclassified base graph object, and a first minor ID value corresponding to the unclassified base graph object, the one major ID value corresponding to the unclassified base graph object being included in the one or more major ID values. It should be noted that a first minor ID value corresponding to an unclassified hardware structure information item may be inferred in inference step S144.

The classification method for the semiconductor integrated circuit according to the present embodiment allows an initial layout data item in design device for semiconductor integrated circuit 60 to include a layout metadata item including, for example, a first minor ID value inferred by classification engine 140. As a result, design device for semiconductor integrated circuit 60 is capable of performing layout design, based on a more detailed layout constraint and a layout script. Accordingly, it is possible to reduce much more computational resources and time, and improve layout quality.

### 2-4. Design Method for Semiconductor Integrated Circuit

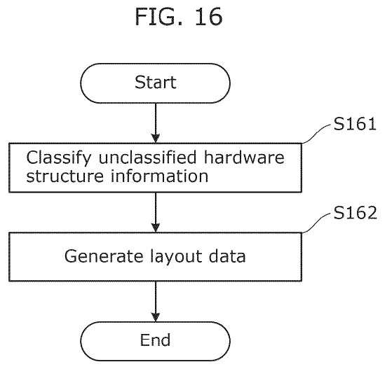

A design method for a semiconductor integrated circuit according to the present embodiment is described with reference to FIG. 16. FIG. 16 is a flow chart illustrating steps in the design method for the semiconductor integrated circuit according to the present embodiment. The design method for the semiconductor integrated circuit according to the present embodiment is performed by design device for semiconductor integrated circuit 60.

In the present embodiment, first, an unclassified hardware structure information item is classified by inferring one major ID value corresponding to the unclassified hardware structure information item, and a first minor ID value, using the above-described classification method for the semiconductor integrated circuit (classification step S161).

Next, design device for semiconductor integrated circuit 60 generates a layout data item which is based on the unclassified hardware structure information item, based on one hardware structure information item corresponding to a combination of the one major ID value and the first minor ID value, and a design data item relating to a layout data item generated based on the one hardware structure information item, the one hardware structure information item being included in a plurality of hardware structure information items (layout data generation step S162).

Consequently, the design method for the semiconductor integrated circuit according to the present embodiment produces the same advantageous effect as the design method for the semiconductor integrated circuit according to Embodiment 1. Additionally, the present embodiment allows an initial layout data used in design device for semiconductor integrated circuit 60 to include a layout metadata item including, for example, a first minor ID value inferred by classification engine 140. As a result, design device for semiconductor integrated circuit 60 is capable of performing layout design, based on a more detailed layout constraint and a layout script. Accordingly, it is possible to reduce much more computational resources and time, and improve layout quality.

### Variations Etc

Although the classification engine training method for the semiconductor integrated circuit etc. according to the present disclosure have been described based on each of the embodiments, the present disclosure is not limited to these embodiments. Forms obtained by various modifications to each of the embodiments that can be conceived by a person skilled in the art as well as other forms realized by combining some of the constituent elements in the embodiment are included in the scope of the present disclosure as long as they do not depart from the essence of the present disclosure.

For example, although the configuration in which the first minor ID value and the second minor ID value are used has been described in Embodiment 2, a combination of a plurality of minor ID values based on a classification result obtained from a plurality of these viewpoints may be assigned as one minor ID value to each graph object.

It should be noted that although the example in which graph objects are used as training and inference targets has been mainly described in each of the above-described embodiments, training and inference targets are not limited to graph objects. For example, training and inference targets may be design data items that make it possible to infer graph objects, or may be design data items corresponding to respective hardware structure information items.

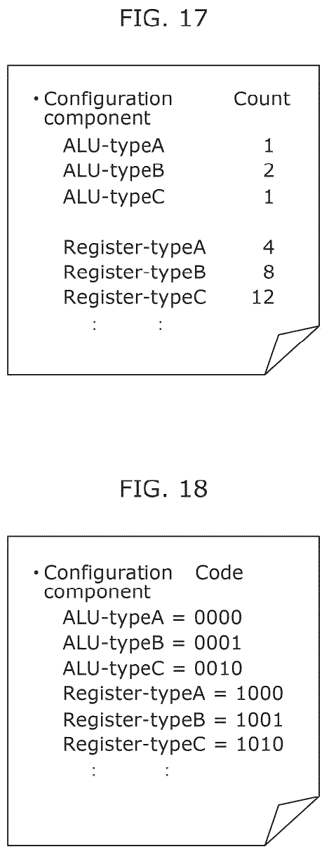

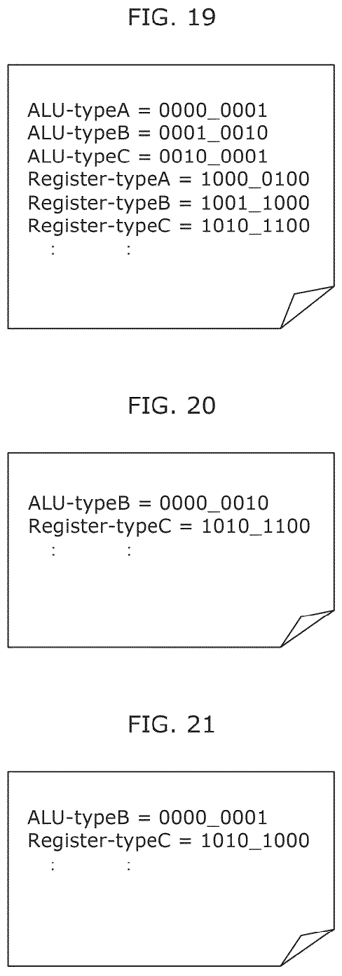

The design data items in this case are described with reference to FIG. 17 to FIG. 21. Each of FIG. 17 and FIG. 18 is a diagram illustrating an example of a design data item. FIG. 19 is a diagram illustrating an example of a base design data item. Each of FIG. 20 and FIG. 21 is a diagram illustrating an example of a partial design data item.

A design data item that is a training and inference target may be, for example, a list of components of an LSI based on an architecture as shown in FIG. 17. As shown in FIG. 18, each component is encoded as an input at the time of training, and as shown in FIG. 19, for example, it is possible to use, as a base design data item, the number of components as a feature. For example, in FIG. 19, a code of component ALU-typeA is indicated by 0000, and the number of components ALU-typeA is indicated by 0001.

The examples as shown in FIG. 20 and FIG. 21 can be considered as partial design data items each generated based on the base design data item as shown in FIG. 19. In the example shown in FIG. 20, some of the components (e.g., components ALU-typeA and ALU-typeC) shown in FIG. 19 are deleted. Moreover, in the example shown in FIG. 21, the number of the components is further reduced from the example shown in FIG. 20. For example, whereas the number of components ALU-typeB shown in FIG. 20 is 0010, the number of components ALU-typeB shown in FIG. 21 is reduced to 0001.

When these base design data items and partial base design data items are used, it is possible to perform training and inference in the same manner as each of the above-described embodiments.

In this case, the neural network used by trainers 26 and 126 and inferrers 44 and 144 as well as in training steps S26 and S126 and inference steps S44 and S144 in each of the above-described embodiments may be, for example, a generic convolutional network or a multi-layer perceptron instead of a graph neural network.

Embodiments described below may also be included in the scope of one or more aspects of the present disclosure.

(1) Some of the constituent elements of design system for semiconductor integrated circuit 10 described above may be a computer system that includes, for example, a microprocessor, a ROM, a RAM, a hard disk unit, a display unit, a keyboard, and a mouse. The RAM or the hard disk unit stores computer programs. The microprocessor achieves its functions by operating in accordance with the computer programs. The computer programs as used herein refer to those configured by combining a plurality of instruction codes that indicate commands given to the computer in order to achieve predetermined functions.

(2) Some of the constituent elements of design system for semiconductor integrated circuit 10 described above may be made up of a single-system large scale integrated (LSI) circuit. The system LSI circuit is an ultra-multifunction LSI circuit manufactured by integrating a plurality of components on a single chip, and is specifically a computer system that includes, for example, a microprocessor, a ROM, and a RAM. The RAM stores computer programs. The system LSI circuit achieves its functions by causing the microprocessor to operate in accordance with the computer programs.

(3) Some of the constituent elements of design system for semiconductor integrated circuit 10 described above may be configured as an IC card or a stand-alone module that is detachable from each device. The IC card or the module is a computer system that includes, for example, a microprocessor, a ROM, and a RAM. The IC card or the module may also be configured to include the ultra-multifunction LSI circuit described above. The IC card or the module achieves its functions by causing the microprocessor to operate in accordance with the computer programs. The IC card or the module may have protection against tampering.

(4) Some of the constituent elements of design system for semiconductor integrated circuit 10 described above may be implemented as a computer-readable recording medium that records the computer programs or the digital signals described above, e.g., may be implemented by recording the computer programs or the digital signals described above on a recording medium such as a flexible disk, a hard disk, a CD-ROM, an MO, a DVD, a DVD-ROM, a DVD-RAM, a Blu-ray disc (BD: registered trademark), or a semiconductor memory. These constituent elements may also be implemented as the digital signals recorded on the recording medium as described above.

Some of the constituent elements of design system for semiconductor integrated circuit 10 described above may be configured to transmit the computer programs or the digital signals described above via, for example, telecommunication lines, wireless or wired communication lines, a network represented by the Internet, or data broadcasting.

(5) The present disclosure may be implemented as the methods described above. The present disclosure may also be implemented as a computer program for causing a computer to execute the methods described above, or may be implemented as digital signals of the computer programs. The present disclosure may also be implemented as a non-transitory computer-readable recording medium such as a CD-ROM that records the above computer programs.

(6) The present disclosure may also be implemented as a computer system that includes a microprocessor and memory, in which the memory may store the computer programs described above and the microprocessor may operate in accordance with the computer programs described above.

(7) The present disclosure may also be implemented as another independent computer system by transferring the above-described programs or digital signals that are recorded on the recording medium described above, or by transferring the above-described programs or digital signals via the network or the like.

(8) The embodiments and variations described above may be combined with one another.

### Supplementary Note

The following techniques are disclosed based on the above descriptions.
(Technique 1) A classification engine training method for a semiconductor integrated circuit, the classification engine training method including: obtaining a base design data item corresponding to each of one or more hardware structure information items that describe the semiconductor integrated circuit and are different from each other; generating a training design data set including a plurality of additional design data items, based on the base design data item; and training a neural network using each of the plurality of additional design data items as an input, in which the plurality of additional design data items are different from each other, and each includes a partial base design data item that is a portion of the base design data item and different from the base design data item, one major ID value is assigned to each of the one or more hardware structure information items, the one major ID value being included in one or more major ID values different from each other, and in the training, the neural network is trained using each of the plurality of additional design data items as the input, to infer one major ID value corresponding to the additional design data item to be used as the input, the one major ID value corresponding to the additional design data item being included in the one or more major ID values.
(Technique 2) The classification engine training method according to Technique 1, in which in the obtaining, a base graph object in a graph object format is obtained as the base design data item, in the generating, the training design data set is generated, the training design data set including a plurality of additional graph objects in the graph object format as the plurality of additional design data items, and the plurality of additional graph objects are different from each other, and each includes, as the partial base design data item, a partial base graph object that is a portion of the base graph object and different from the base graph object.
(Technique 3) The classification engine training method according to Technique 2, in which the base graph object includes a plurality of base nodes and one or more base edges, each of the plurality of base nodes corresponds to a hardware instance achieving a function represented by a hardware structure information item corresponding to the base graph object, the hardware structure information item being included in the one or more hardware structure information items, and each of the one or more base edges corresponds to a connector connected to the hardware instance.
(Technique 4) The classification engine training method according to Technique 3, in which the partial base graph object includes a plurality of partial nodes, and a total number of the plurality of partial nodes is larger than half of a total number of the plurality of base nodes.
(Technique 5) The classification engine training method according to Technique 4, in which the plurality of additional graph objects include a combined graph object that is a combination of the partial base graph object and a noise graph object, and a total number of nodes included in the noise graph object is smaller than the total number of the plurality of partial nodes.
(Technique 6) The classification engine training method according to any one of Techniques 1 to 5, in which the one or more hardware structure information items include a plurality of hardware structure information items.
(Technique 7) The classification engine training method according to Technique 6, in which a first minor ID value based on a classification result obtained from a first viewpoint is assigned to each of the plurality of additional design data items each of which corresponds to a different one of the plurality of hardware structure information items, and in the training, the neural network is further trained to infer the first minor ID value corresponding to an additional design data item to be used as an input to the neural network, the additional design data item being included in the plurality of additional design data items.
(Technique 8) The classification engine training method according to Technique 7, in which in the generating, the training design data set is generated, the training design data set including a plurality of additional graph objects in a graph object format as the plurality of additional design data items, each of the plurality of additional graph objects includes a plurality of additional nodes and one or more additional edges, and the first viewpoint relates to features of the plurality of additional nodes and one or more features of the one or more additional edges.
(Technique 9) The classification engine training method according to Technique 7, in which in the generating, the training design data set is generated, the training design data set including a plurality of additional graph objects in a graph object format as the plurality of additional design data items, a second minor ID value based on a classification result obtained from a second viewpoint is assigned to each of the plurality of additional graph objects each of which corresponds to a different one of the plurality of hardware structure information items, the second viewpoint being different from the first viewpoint, and in the training, the neural network is trained to infer the second minor ID value corresponding to an additional graph object to be used as an input to the neural network, the additional graph object being included in the plurality of additional graph objects.
(Technique 10) The classification engine training method according to any one of Techniques 3 to 5, in which in the generating, the plurality of base nodes included in the base graph object are classified into a plurality of groups, based on first features of the plurality of base nodes, the plurality of groups including a first group and a second group, the partial base graph object includes a plurality of partial nodes, the plurality of partial nodes included in the partial base graph object include, among the plurality of base nodes included in the base graph object, a base node included in the first group and a base node included in the second group, and a range of first features corresponding to the first group includes a representative value of the first features of the plurality of base nodes, the first features corresponding to the first group being included in the first features of the plurality of base nodes.
(Technique 11) The classification engine training method according to Technique 10, in which the representative value is a median, a mean, or a mode of the first features of the plurality of base nodes.
(Technique 12) The classification engine training method according to any one of Techniques 3 to 5, in which the plurality of base nodes include one or more first base nodes, and each of the one or more first base nodes has, as a feature, a degree of computational complexity in the hardware instance corresponding to the first base node.
(Technique 13) The classification engine training method according to any one of Techniques 3 to 5, in which the plurality of base nodes include one or more second base nodes, and each of the one or more second base nodes has, as a feature, a total number of inputs to the second base node.
(Technique 14) The classification engine training method according to any one of Techniques 3 to 5, in which the one or more base edges include one or more first base edges, and each of the one or more first base edges has, as a feature, an amount of information transmitted by the connector corresponding to the first base edge.
(Technique 15) The classification engine training method according to any one of Techniques 1 to 14, in which each of the one or more hardware structure information items is a gate level netlist. (Technique 16) The classification engine training method according to any one of Techniques 3 to 5, in which the plurality of base nodes include one or more third base nodes, and each of the one or more third base nodes has, as a feature, a total number of base nodes through which an input to the third base node passes, the base nodes being included in the plurality of base nodes.
(Technique 17) A classification method for a semiconductor integrated circuit, the classification method including: preparing the neural network trained by the classification engine training method according to any one of Techniques 1 to 16; obtaining an unclassified base design data item corresponding to an unclassified hardware structure information item different from the one or more hardware structure information items; and inferring one major ID value corresponding to the unclassified base design data item, by inputting the unclassified base design data item to the neural network trained, the one major ID value corresponding to the unclassified base design data item being included in the one or more major ID values, in which the one or more hardware structure information items include a plurality of hardware structure information items.
(Technique 18) A classification method for a semiconductor integrated circuit in which the neural network trained by the classification engine training method according to Technique 7 is used, the classification method including: obtaining an unclassified base design data item corresponding to an unclassified hardware structure information item different from the one or more hardware structure information items; and by inputting the unclassified base design data item to the neural network trained, inferring one major ID value corresponding to the unclassified base design data item, and inferring the first minor ID value corresponding to the unclassified base design data item, the one major ID value corresponding to the unclassified base design data item being included in the one or more major ID values.
(Technique 19) A classification method for a semiconductor integrated circuit, the classification method including: assigning one major ID value to each of a plurality of hardware structure information items, based on the plurality of hardware structure information items and a layout data item about a semiconductor integrated circuit, the one major ID value being included in a plurality of major ID values different from each other, the plurality of hardware structure information items describing the semiconductor integrated circuit and being different from each other, the layout data item being generated based on each of the plurality of hardware structure information items; obtaining an unclassified base design data item corresponding to an unclassified hardware structure information item different from the plurality of hardware structure information items; and inferring one major ID value corresponding to the unclassified base design data item, by inputting the unclassified base design data item to a neural network trained, the one major ID value corresponding to the unclassified base design data item being included in the plurality of major ID values.
(Technique 20) The classification method according to Technique 19, in which in the obtaining, an unclassified base graph object in a graph object format is obtained as the unclassified base design data item.
(Technique 21) The classification method according to Technique 19, in which the neural network has been trained by a classification engine training method, the classification engine training method includes: obtaining a base design data item corresponding to each of the plurality of hardware structure information items; generating a training design data set including a plurality of additional design data items, based on the base design data item; and training the neural network using each of the plurality of additional design data items as an input, the plurality of additional design data items are different from each other, and each includes a partial base design data item that is a portion of the base design data item and different from the base design data item, and in the training, the neural network is trained using each of the plurality of additional design data items as an input, to infer one major ID value corresponding to the additional design data item to be used as the input, the one major ID value corresponding to the additional design data item being included in the plurality of major ID values.
(Technique 22) A design method for a semiconductor integrated circuit, the design method including: classifying the unclassified hardware structure information item by inferring the one major ID value by the classification method according to Technique 19; and generating a layout data item which is based on the unclassified hardware structure information item, based on one hardware structure information item to which the one major ID value is assigned, and a design data item relating to a layout data item generated based on the one hardware structure information item, the one hardware structure information item being included in the plurality of hardware structure information items.
(Technique 23) The classification method according to Technique 19, in which a first minor ID value based on a classification result obtained from a first viewpoint is assigned to each of the plurality of hardware structure information data items, and in the inferring, the first minor ID value corresponding to the unclassified hardware structure information item is further inferred.
(Technique 24) A design method for a semiconductor integrated circuit, the design method including: classifying the unclassified hardware structure information item by inferring, by the classification method according to Technique 23, the one major ID value and the first minor ID value that correspond to the unclassified hardware structure information item; and generating a layout data item which is based on the unclassified hardware structure information item, based on one hardware structure information item corresponding to a combination of the one major ID value and the first minor ID value, and a design data item relating to a layout data item generated based on the one hardware structure information item, the one hardware structure information item being included in the plurality of hardware structure information items.

Although only some exemplary embodiments of the present disclosure have been described in detail above, those skilled in the art will readily appreciate that many modifications are possible in the exemplary embodiments without materially departing from the novel teachings and advantages of the present disclosure. Accordingly, all such modifications are intended to be included within the scope of the present disclosure.

### INDUSTRIAL APPLICABILITY

The present disclosure can be used when a layout of a semiconductor integrated circuit is designed based on a hardware structure information item describing the semiconductor integrated circuit.

1. A classification engine training method for a semiconductor integrated circuit, the classification engine training method comprising:
obtaining a base design data item corresponding to each of one or more hardware structure information items that describe the semiconductor integrated circuit and are different from each other;
generating a training design data set including a plurality of additional design data items, based on the base design data item; and
training a neural network using each of the plurality of additional design data items as an input,
wherein the plurality of additional design data items are different from each other, and each includes a partial base design data item that is a portion of the base design data item and different from the base design data item,
one major ID value is assigned to each of the one or more hardware structure information items, the one major ID value being included in one or more major ID values different from each other, and
in the training, the neural network is trained using each of the plurality of additional design data items as the input, to infer one major ID value corresponding to the additional design data item to be used as the input, the one major ID value corresponding to the additional design data item being included in the one or more major ID values.

2. The classification engine training method according to claim 1,
wherein in the obtaining, a base graph object in a graph object format is obtained as the base design data item,
in the generating, the training design data set is generated, the training design data set including a plurality of additional graph objects in the graph object format as the plurality of additional design data items, and
the plurality of additional graph objects are different from each other, and each includes, as the partial base design data item, a partial base graph object that is a portion of the base graph object and different from the base graph object.

3. The classification engine training method according to claim 2,
wherein the base graph object includes a plurality of base nodes and one or more base edges,
each of the plurality of base nodes corresponds to a hardware instance achieving a function represented by a hardware structure information item corresponding to the base graph object, the hardware structure information item being included in the one or more hardware structure information items, and
each of the one or more base edges corresponds to a connector connected to the hardware instance.

4. The classification engine training method according to claim 3,
wherein the partial base graph object includes a plurality of partial nodes, and
a total number of the plurality of partial nodes is larger than half of a total number of the plurality of base nodes.

5. The classification engine training method according to claim 4,
wherein the plurality of additional graph objects include a combined graph object that is a combination of the partial base graph object and a noise graph object, and
a total number of nodes included in the noise graph object is smaller than the total number of the plurality of partial nodes.

6. The classification engine training method according to claim 1,
wherein the one or more hardware structure information items include a plurality of hardware structure information items.

7. The classification engine training method according to claim 6,
wherein a first minor ID value based on a classification result obtained from a first viewpoint is assigned to each of the plurality of additional design data items each of which corresponds to a different one of the plurality of hardware structure information items, and
in the training, the neural network is further trained to infer the first minor ID value corresponding to an additional design data item to be used as an input to the neural network, the additional design data item being included in the plurality of additional design data items.

8. The classification engine training method according to claim 7,
wherein in the generating, the training design data set is generated, the training design data set including a plurality of additional graph objects in a graph object format as the plurality of additional design data items,
each of the plurality of additional graph objects includes a plurality of additional nodes and one or more additional edges, and
the first viewpoint relates to features of the plurality of additional nodes and one or more features of the one or more additional edges.

9. The classification engine training method according to claim 7,
wherein in the generating, the training design data set is generated, the training design data set including a plurality of additional graph objects in a graph object format as the plurality of additional design data items,
a second minor ID value based on a classification result obtained from a second viewpoint is assigned to each of the plurality of additional graph objects each of which corresponds to a different one of the plurality of hardware structure information items, the second viewpoint being different from the first viewpoint, and
in the training, the neural network is trained to infer the second minor ID value corresponding to an additional graph object to be used as an input to the neural network, the additional graph object being included in the plurality of additional graph objects.

10. The classification engine training method according to claim 3,
wherein in the generating, the plurality of base nodes included in the base graph object are classified into a plurality of groups, based on first features of the plurality of base nodes, the plurality of groups including a first group and a second group,
the partial base graph object includes a plurality of partial nodes,
the plurality of partial nodes included in the partial base graph object include, among the plurality of base nodes included in the base graph object, a base node included in the first group and a base node included in the second group, and
a range of first features corresponding to the first group includes a representative value of the first features of the plurality of base nodes, the first features corresponding to the first group being included in the first features of the plurality of base nodes.

11. The classification engine training method according to claim 10,
wherein the representative value is a median, a mean, or a mode of the first features of the plurality of base nodes.

12. The classification engine training method according to claim 3,
wherein the plurality of base nodes include one or more first base nodes, and
each of the one or more first base nodes has, as a feature, a degree of computational complexity in the hardware instance corresponding to the first base node.

13. The classification engine training method according to claim 3,
wherein the plurality of base nodes include one or more second base nodes, and
each of the one or more second base nodes has, as a feature, a total number of inputs to the second base node.

14. The classification engine training method according to claim 3,
wherein the one or more base edges include one or more first base edges, and
each of the one or more first base edges has, as a feature, an amount of information transmitted by the connector corresponding to the first base edge.

15. The classification engine training method according to claim 1,
wherein each of the one or more hardware structure information items is a gate level netlist.

16. The classification engine training method according to claim 3,
wherein the plurality of base nodes include one or more third base nodes, and
each of the one or more third base nodes has, as a feature, a total number of base nodes through which an input to the third base node passes, the base nodes being included in the plurality of base nodes.

17. A classification method for a semiconductor integrated circuit, the classification method comprising:
preparing the neural network trained by the classification engine training method according to claim 1;
obtaining an unclassified base design data item corresponding to an unclassified hardware structure information item different from the one or more hardware structure information items; and
inferring one major ID value corresponding to the unclassified base design data item, by inputting the unclassified base design data item to the neural network trained, the one major ID value corresponding to the unclassified base design data item being included in the one or more major ID values,
wherein the one or more hardware structure information items include a plurality of hardware structure information items.

18. A classification method for a semiconductor integrated circuit in which the neural network trained by the classification engine training method according to claim 7 is used, the classification method comprising:
obtaining an unclassified base design data item corresponding to an unclassified hardware structure information item different from the one or more hardware structure information items; and
by inputting the unclassified base design data item to the neural network trained, inferring one major ID value corresponding to the unclassified base design data item, and inferring the first minor ID value corresponding to the unclassified base design data item, the one major ID value corresponding to the unclassified base design data item being included in the one or more major ID values.

19. A classification method for a semiconductor integrated circuit, the classification method comprising:
assigning one major ID value to each of a plurality of hardware structure information items, based on the plurality of hardware structure information items and a layout data item about a semiconductor integrated circuit, the one major ID value being included in a plurality of major ID values different from each other, the plurality of hardware structure information items describing the semiconductor integrated circuit and being different from each other, the layout data item being generated based on each of the plurality of hardware structure information items;
obtaining an unclassified base design data item corresponding to an unclassified hardware structure information item different from the plurality of hardware structure information items; and
inferring one major ID value corresponding to the unclassified base design data item, by inputting the unclassified base design data item to a neural network trained, the one major ID value corresponding to the unclassified base design data item being included in the plurality of major ID values.

20. The classification method according to claim 19,
wherein in the obtaining, an unclassified base graph object in a graph object format is obtained as the unclassified base design data item.

21. The classification method according to claim 19,
wherein the neural network has been trained by a classification engine training method,
the classification engine training method includes:
obtaining a base design data item corresponding to each of the plurality of hardware structure information items;
generating a training design data set including a plurality of additional design data items, based on the base design data item; and
training the neural network using each of the plurality of additional design data items as an input,
the plurality of additional design data items are different from each other, and each includes a partial base design data item that is a portion of the base design data item and different from the base design data item, and
in the training, the neural network is trained using each of the plurality of additional design data items as an input, to infer one major ID value corresponding to the additional design data item to be used as the input, the one major ID value corresponding to the additional design data item being included in the plurality of major ID values.

22. A design method for a semiconductor integrated circuit, the design method comprising:
classifying the unclassified hardware structure information item by inferring the one major ID value by the classification method according to claim 19; and
generating a layout data item which is based on the unclassified hardware structure information item, based on one hardware structure information item to which the one major ID value is assigned, and a design data item relating to a layout data item generated based on the one hardware structure information item, the one hardware structure information item being included in the plurality of hardware structure information items.

23. The classification method according to claim 19,
wherein a first minor ID value based on a classification result obtained from a first viewpoint is assigned to each of the plurality of hardware structure information data items, and
in the inferring, the first minor ID value corresponding to the unclassified hardware structure information item is further inferred.

24. A design method for a semiconductor integrated circuit, the design method comprising:
classifying the unclassified hardware structure information item by inferring, by the classification method according to claim 23, the one major ID value and the first minor ID value that correspond to the unclassified hardware structure information item; and
generating a layout data item which is based on the unclassified hardware structure information item, based on one hardware structure information item corresponding to a combination of the one major ID value and the first minor ID value, and a design data item relating to a layout data item generated based on the one hardware structure information item, the one hardware structure information item being included in the plurality of hardware structure information items.
